(19) United States
(12) Patent Application Publication
(10) Pub. No.: US 2025/0232072 A1
(43) Pub. Date: Jul. 17, 2025

(54) ENVIRONMENT ESTIMATION METHOD AND RECORDING MEDIUM

(71) Applicant: Panasonic Intellectual Property Management Co., Ltd., Osaka (JP)

(72) Inventors: Hirofumi KUBOTA, Osaka (JP); Junya OGAWA, Osaka (JP); Jiangpeng YU, Osaka (JP); Naoki MURO, Nara (JP); Katsuya HABARA, Osaka (JP); Hideo NAGAHAMA, Nara (JP)

(21) Appl. No.: 18/703,953

(22) PCT Filed: Oct. 20, 2022
(86) PCT No.: PCT/JP2022/039144

§ 371 Date: Apr. 23, 2024

(30) Foreign Application Priority Data
Nov. 12, 2021 (JP) 2021-184917

(51) Int. Cl. G06F 30/13; F24F 11/74; F24F 110/20

(52) U.S. Cl. CPC G06F 30/13; F24F 11/74; F24F 2110/20

(57) ABSTRACT

An environment estimation method includes: acquiring first information regarding a total number of ventilations for an indoor space and second information regarding an amount of humidification for the indoor space; acquiring size information indicating a size of the indoor space and the like; generating BIM data of a building that defines the indoor space; acquiring a calculation condition and the like; generating a simulation model of an environment of the indoor space; and executing a simulation of the environment of the indoor space by using the simulation model generated.

### CROSS-REFERENCE OF RELATED APPLICATIONS

This application is the U.S. National Phase under 35 U.S.C. § 371 of International Patent Application No. PCT/JP2022/039144, filed on Oct. 20, 2022, which in turn claims the benefit of Japanese Patent Application No. 2021-184917, filed on Nov. 12, 2021, the entire disclosure of which Applications are incorporated by reference herein.

### TECHNICAL FIELD

The present invention relates to an environment estimation method and a recording medium.

### BACKGROUND ART

Conventionally, techniques for simulating an internal environment of a building such as a house are proposed. Patent Literature (PTL) 1 discloses a living environment simulation system that can present a comfort level at each position in a building.

### CITATION LIST

### Patent Literature

### PTL 1

Japanese Unexamined Patent Application Publication No. 2021-33684

### SUMMARY OF INVENTION

### Technical Problem

The present invention provides an environment estimation method with which it is possible to simulate an environment of indoor space by taking into consideration the influence of ventilation, and a recording medium.

### Solution to Problem

An environment estimation method according to an aspect of the present invention includes: acquiring at least one of first information or second information, the first information being information regarding a total number of ventilations for an indoor space, the second information being information regarding an amount of humidification for the indoor space; acquiring size information indicating a size of the indoor space, arrangement information indicating an arrangement of equipment and fixtures in the indoor space, and specification information of the equipment and the fixtures; generating building information modeling (BIM) data of a building that defines the indoor space, based on the size information acquired, the arrangement information acquired, and the specification information acquired; acquiring a calculation condition that includes a mesh size set for the BIM data, a solar radiation condition, and an outside air condition; generating a simulation model of an environment of the indoor space based on the at least one of the first information or the second information acquired, the BIM data generated, the calculation condition acquired, the solar radiation condition acquired, and the outside air condition acquired; and executing a simulation of the environment of the indoor space by using the simulation model generated.

A recording medium according to an aspect of the present invention is a computer-readable non-transitory recording medium in which a program for causing a computer to execute the above-described environment estimation method is recorded.

### Advantageous Effects of Invention

According to the environment estimation method and the recording medium according to an aspect of the present invention, it is possible to simulate an environment of indoor space by taking into consideration the influence of ventilation.

### BRIEF DESCRIPTION OF DRAWINGS

FIG. 1 is a block diagram showing a functional configuration of an environment estimation system according to an embodiment.

FIG. 2 is a diagram showing an example of an indoor space to be simulated by the environment estimation system according to the embodiment.

FIG. 3 is a flowchart illustrating an example of a procedure for obtaining actual measurement data in the indoor space.

FIG. 4 is a flowchart of operation example 1 of the environment estimation system according to the embodiment.

FIG. 5 is a diagram showing an example of conversion to a simplified model.

FIG. 6 is a diagram showing an example of calculation condition setting information.

FIG. 7 is a flowchart of operation example 2 of the environment estimation system according to the embodiment.

### DESCRIPTION OF EMBODIMENTS

Hereinafter, embodiments will be described with reference to the drawings. The embodiments described below show generic or specific examples of the present invention. The numerical values, shapes, materials, structural elements, the arrangement and connection of the structural elements, steps, the order of the steps, and the like shown in the following embodiments are merely examples, and therefore are not intended to limit the scope of the present invention. Also, among the structural elements described in the following embodiments, structural elements not recited in any one of the independent claims are described as arbitrary structural elements.

Note that the diagrams are schematic representations, and thus are not necessarily true to scale. Also, in the diagrams, structural elements that are substantially the same are given the same reference numerals, and a redundant description may be omitted or simplified.

### Embodiment

### Configuration

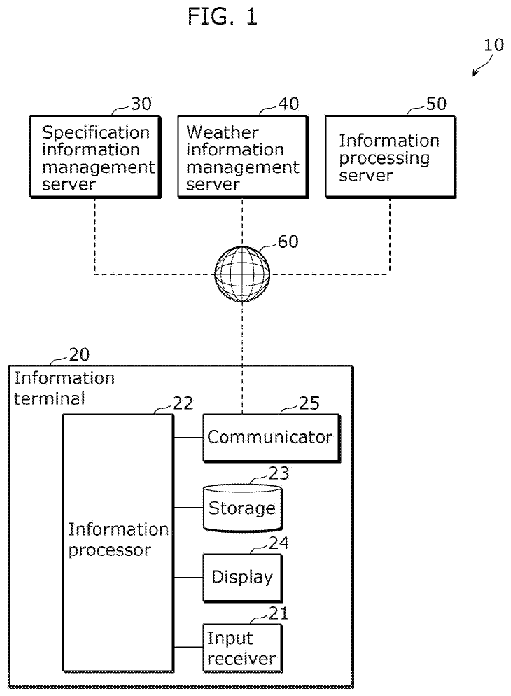

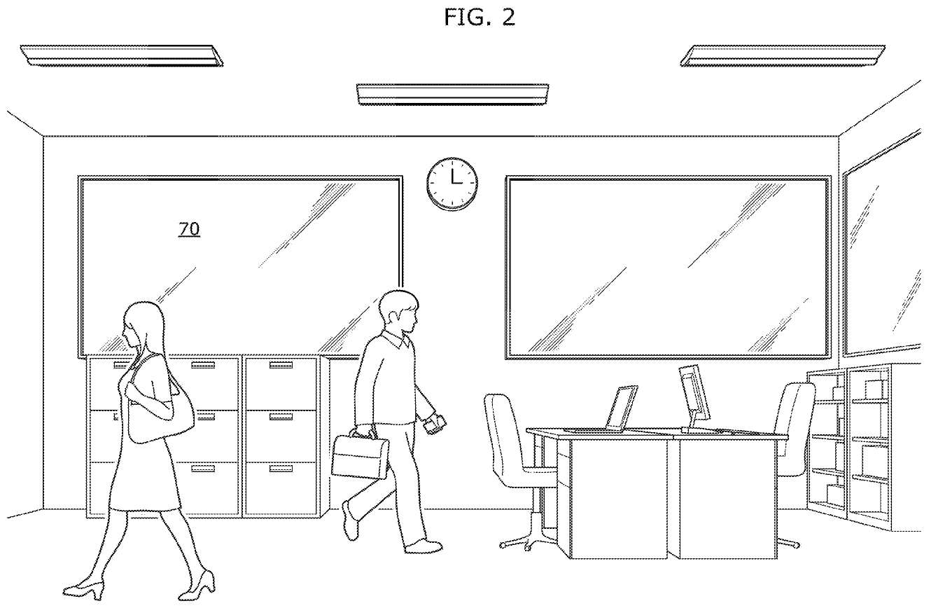

First, an overview of an environment estimation system according to an embodiment will be described. FIG. 1 is a block diagram showing a functional configuration of the environment estimation system according to the embodiment. FIG. 2 is a diagram showing an example of an indoor space to be simulated by the environment estimation system according to the embodiment.

Environment estimation system 10 is a system that can simulate the environment of indoor space 70 of a building such as an office. The environment of indoor space 70 specifically refers to a thermal environment and an air quality environment. The thermal environment is specifically expressed by an environmental parameter such as temperature, humidity, or wind speed. The air quality environment is specifically expressed by an environmental parameter such as carbon dioxide concentration, formaldehyde concentration, or fine particulate concentration (particulate matter (PM) concentration).

For example, environment estimation system 10 simulates the actual environment of indoor space 70, and further simulates an assumed environment in which new equipment is installed in indoor space 70. The new equipment refers to, for example, ventilation equipment such as a total heat exchanger, air conditioning equipment, or the like.

With results (images) of the two types of simulations, a salesperson who belongs to a manufacturer of the new equipment can present the simulation results to a manager or owner (hereinafter, also referred to as “manager or the like”) of the building to show how the environment of indoor space 70 changes before and after installation of the equipment. In other words, the appeal for installing new equipment can be improved.

Specifically, environment estimation system 10 includes information terminal 20, specification information management server 30, weather information management server 40, and information processing server 50. Hereinafter, the devices included in environment estimation system 10 will be described.

Information terminal 20 is a calculator that performs environmental simulation on indoor space 70 such as, for example, a personal computer. Information terminal 20 includes input receiver 21, information processor 22, storage 23, display 24, and communicator 25.

Input receiver 21 receives user inputs. Input receiver 21 is, for example, an input device such as a mouse or a keyboard, and receives a user operation (a click operation or the like) as an input. Input receiver 21 may be another input device such as a touch panel. In this case, input receiver 21 receives a user's tap operation or the like as an input.

Information processor 22 simulates the environment of indoor space 70. Information processor 22 is implemented by, for example, a microcomputer, but may be implemented by a processor. The functions of information processor 22 are implemented by the microcomputer, the processor or the like that constitutes information processor 22 executing a computer program stored in storage 23.

Storage 23 is a storage device in which the computer program that is executed by information processor 22 and the like are stored. Storage 23 is implemented by, for example, a semiconductor memory.

Display 24 displays a display screen for the environmental simulation performed on indoor space 70. Also, display 24 displays a display screen showing a three dimensional distribution (or in other words, a simulation result) of the temperature, humidity, wind speed, carbon dioxide concentration, formaldehyde concentration, or fine particulate concentration in indoor space 70, or the like. Display 24 is implemented by, for example, a display panel such as a liquid crystal panel or an organic electroluminescent (EL) panel.

Communicator 25 is a communication circuit (communication module) for information terminal 20 to perform communication with specification information management server 30, weather information management server 40, and information processing server 50 via wide area communication network 60 such as the Internet. Communicator 25 is, for example, a wired communication circuit that performs wired communication, but may be a wireless communication circuit that performs wireless communication. There is no particular limitation on the communications standard used by communicator 25.

Specification information management server 30 is a cloud computer that manages specification information that indicates design specifications of equipment and fixtures, and provides the specifications of equipment and fixtures to information terminal 20. The term “specification information” is interchangeable with “catalog information” or the like.

Weather information management server 40 is a cloud computer that manages current or past weather information, and provides the weather information to information terminal 20. The weather information includes solar radiation amount information, ambient temperature information, humidity information, and the like.

Information processing server 50 is a cloud computer that assists the simulation performed by information terminal 20. Information processing server 50 functions as, for example, a storage server that stores simulation data. However, information processing server 50 may be linked to information terminal 20 to execute some or all of the processing operations executed by information terminal 20.

### Actual Measurement Data Required for Simulation

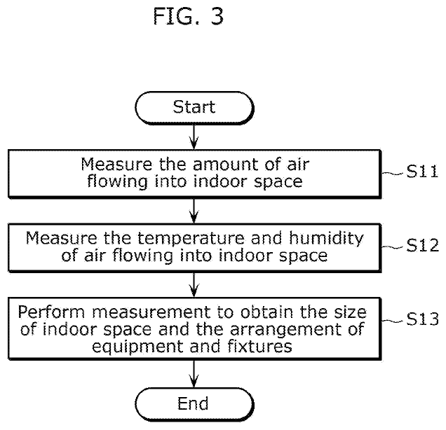

Data required for simulation performed by environment estimation system 10 is obtained by, for example, a measurer such as a salesperson of a manufacturer of the new equipment visiting the building (indoor space 70) and actually measuring the data. FIG. 3 is a flowchart illustrating an example of a procedure for obtaining actual measurement data in indoor space 70.

First, the measurer measures the amount of air flow flowing into indoor space 70 at an air intake port (an opening portion for allowing air to flow into indoor space 70) in indoor space 70 (S11). For example, a portable air flow meter is used to measure the amount of air flow. The amount of air flow may also be measured at an air discharge port (an opening portion for allowing air to discharge from indoor space 70).

The measured amount of air flow is used to calculate the total number of ventilations together with the size of indoor space 70 that is measured in step S13, which will be described later. As used herein, the term “the total number of ventilations” is a parameter that indicates the number of times the entire air in indoor space 70 is exchanged per unit time, and is expressed in the unit of, for example, the total number of ventilations [count]/time [h].

Also, the measurer measures, at the air intake port, the temperature and humidity of air flowing into indoor space 70 (S12). For example, a portable thermometer and a portable hygrometer are used to measure the temperature and humidity. As used herein, the term “humidity” primarily refers to relative humidity. The relative humidity can be easily measured by using a portable hygrometer.

The measured temperature and humidity is used to calculate the amount of humidification together with the amount of air flow that was measured in step S11. As used herein, the term “the amount of humidification” is a parameter that indicates how much moisture is supplied to indoor space 70 per unit time, and is expressed in the unit of, for example, moisture content [g]/time [h].

Also, the measurer performs measurement to obtain the size (volume) of indoor space 70 and the arrangement of existing equipment and existing fixtures that are already installed in indoor space 70 (S13). Hereinafter, size information that indicates the size of the indoor space and arrangement information that indicates the arrangement of the equipment and the fixtures will be also referred to collectively as “structure data”.

The measurer measures the structure data by using, for example, a portable laser range finder, but may measure the structure data by using a three dimensional scanner or the like. Also, the measurer may also acquire the structure data by capturing an image of indoor space 70 by using a smartphone that has a light detection and ranging (LIDAR) function.

The measured structure data is used to generate building information modeling (BIM) data. The BIM data is data in which a plurality of types of data related to the building are combined. The BIM data includes data (three dimensional CAD data and the like) regarding the shape and dimensions of the building that defines indoor space 70, data regarding the equipment and the fixtures installed in indoor space 70, and the like. Also, the BIM data according to the present embodiment also includes various types of data required to implement the environmental simulation in indoor space 70.

The measurer may further measure the temperature, humidity, and air quality in indoor space 70, and the like. The air quality means, for example, carbon dioxide concentration, fine particulate concentration, and the like. By doing so, the manufacturer of the new equipment can more accurately understand the current situation of indoor space 70.

### Operation 1: Operation Example for Simulating Current Environment

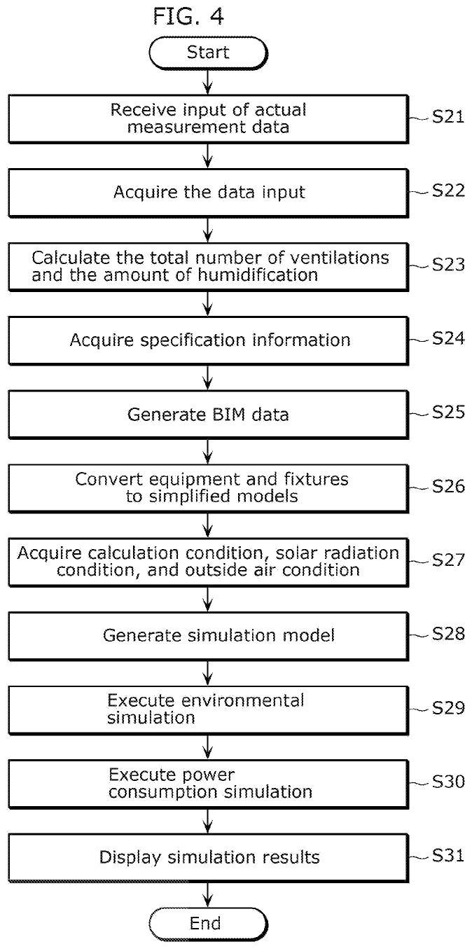

Next, a simulation operation (operation example 1) for simulating the current environment of indoor space 70 before new equipment is installed will be described. FIG. 4 is a flowchart of operation example 1 performed by environment estimation system 10.

First, input receiver 21 of information terminal 20 receives, from an operator who performs the simulation work, an input of actual measurement data obtained through the procedure shown in FIG. 3 (S21). The input data includes air flow amount data regarding the amount of air flow flowing into indoor space 70, air temperature data regarding the temperature of air flowing into indoor space 70, air humidity data regarding the humidity of air flowing into indoor space 70, and structure data. The structure data contains size information indicating the size (volume) of indoor space 70 and arrangement information indicating the arrangement of existing equipment and existing fixtures that have been installed in indoor space 70. Information processor 22 acquires the data input in step S21 (S22).

Next, information processor 22 calculates, based on the data acquired in step S22, the total number of ventilations for indoor space 70 and the amount of humidification of indoor space 70 by the air flowing into indoor space 70 (S23). As described above, the total number of ventilations is the parameter that indicates the number of times the entire air in indoor space 70 is exchanged per unit time. Information processor 22 can calculate the total number of ventilations based on the air flow amount data and the size information included in the structure data out of the data acquired in step S22.

Also, the amount of humidification is the parameter that indicates how much moisture is supplied from the air intake port to indoor space 70. Information processor 22 can calculate the amount of humidification based on the air flow amount data, the air temperature data, and the air humidity data out of the data acquired in step S22.

The processing performed in step S23 is, in other words, processing for acquiring first information and second information, the first information being determined based on actual measurement data and directly indicating the total number of ventilations for indoor space 70, the second information being determined based on actual measurement data and directly inducting the amount of humidification of indoor space 70 by the air flowing into indoor space 70.

Next, information processor 22 acquires, from specification information management server 30, specification information of existing equipment and existing fixtures specified by the arrangement information acquired in step S22 (S24). Specifically, information processor 22 transmits the product number of each of the equipment and the fixtures included in the arrangement information to specification information management server 30 via communicator 25. By doing so, information processor 22 can acquire the specification of existing equipment and existing fixtures installed in indoor space 70 as a response from specification information management server 30. The specification information includes three dimensional CAD data of the equipment and the fixtures, equipment settings information, and the like. As used herein, the term “equipment” refers to ventilation equipment, air conditioning equipment, lighting equipment, and the like.

Next, information processor 22 generates BIM data of the building that defines indoor space 70, based on the size information and the arrangement information acquired in step S22, and the specification information acquired in step S24 (S25).

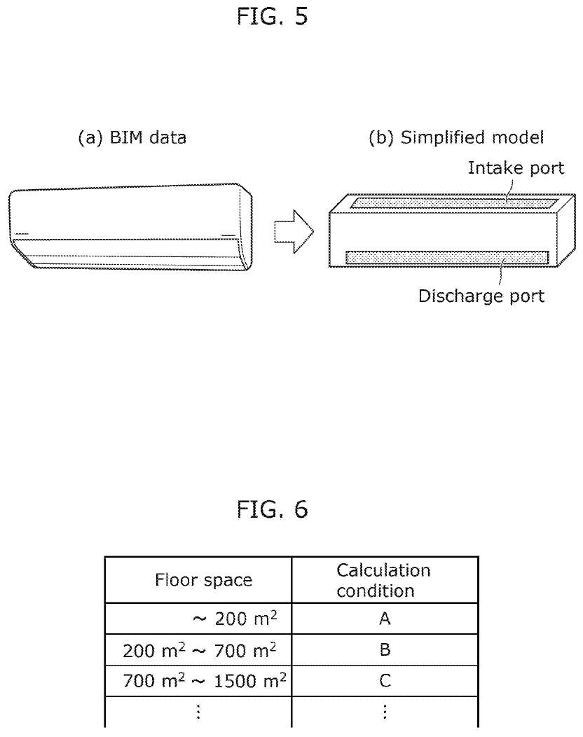

Here, in the generated BIM data (three dimensional CAD data), the equipment and the fixtures are converted into detailed models based on the specification information. Accordingly, information processor 22 converts each of the equipment and the fixtures in the generated BIM data into a simplified model by using a predetermined algorithm (S26). FIG. 5 is a diagram showing an example of a simplified model obtained through conversion. As shown in FIG. 5, the simplified model is constructed only by a simple structural element such as a rectangular parallelepiped and flat surfaces, and has no curved surface. In other words, the simplified model can be obtained by converting the actual shape of each of the equipment and the fixtures specified by the specification information into a shape without a curved surface.

With the simplified model as described above, it is possible to use an orthogonal mesh that divides a space only in vertical and horizontal directions. The total number of meshes used in a simulation model is reduced, and thus the calculation time required for simulation can be shortened. It is also possible to obtain the effect of stabilizing convergence of solution to the simulation. The occupied volume of a curved surface of the equipment and the fixtures is smaller than that of a large space such as indoor space 70, and it is therefore considered that even if the curved surface is simplified, there is a small substantial influence on simulation results.

Next, information processor 22 acquires a calculation condition, a solar radiation condition, and an outside air condition (S27). The calculation condition includes mesh size, calculation cycle, and the like set for the BIM data. The calculation condition is designated by, for example, an operator's input operation performed on input receiver 21. As used herein, the term “mesh” refers to a unit used when a simulation target object is divided into an element of a simple shape.

Also, information processor 22 acquires the solar radiation condition and the outside air condition from weather information management server 40. Specifically, information processor 22 can acquire the solar radiation condition (solar radiation amount information) and the outside air condition (ambient temperature information and outside air humidity information) from weather information management server 40 based on the operator's input operation performed on input receiver 21.

In step S27, information processor 22 may calculate the floor space of indoor space 70 based on the BIM data generated in step S25, and acquire the calculation condition corresponding to the calculated floor space. In this case, storage 23 stores the magnitude of the floor space and calculation condition setting information associated with the calculation condition used at this time. FIG. 6 is a diagram showing an example of the calculation condition setting information. Each calculation condition in the calculation condition setting information is generated, for example, empirically or experimentally by a designer and the like of the environment estimation system.

The entire calculation condition does not necessarily need to be changed according to the floor space, it is sufficient that at least the mesh size is changed according to the floor space. As a result of the mesh size being changed as appropriate according to the floor space, the calculation time required for simulation can be shortened.

Here, a minimum dimension of the simplified model obtained in step S26 can be set to at least the smallest mesh size among mesh sizes that can be selected in environment estimation system 10. By doing so, it is easy to apply a mesh to a simplified model.

After step S27, information processor 22 generates a simulation model of the environment of indoor space 70 based on the total number of ventilations and the amount of humidification calculated in step S23, the BIM data generated in steps S25 and S26, and the calculation condition, the solar radiation condition, and the outside air condition acquired in step S27 (S28).

Also, information processor 22 executes an environmental simulation in indoor space 70 by using the simulation model generated in step S28 (S29). Information processor 22 can calculate, for example, a three dimensional distribution of an environmental parameter in indoor space 70 when the existing equipment (ventilation equipment, air conditioning equipment, lighting equipment, and the like) in indoor space 70 is operated under the various types of conditions acquired in step S27 so as to bring the current environment closer to a predetermined environment (target).

As used herein, the term “environmental parameter” refers to temperature, humidity, wind speed, carbon dioxide concentration, formaldehyde concentration, PM concentration, or the like. The temperature, humidity, and wind speed are examples of environmental parameters in a thermal environment, and the carbon dioxide concentration, formaldehyde concentration, and PM concentration are examples of environmental parameters in an air quality environment. It is sufficient that, in step S29, information processor 22 calculates a three dimensional distribution of at least one of temperature, humidity, wind speed, carbon dioxide concentration, formaldehyde concentration, or PM concentration.

Also, information processor 22 executes a power consumption simulation for the existing equipment installed in indoor space 70 by using the simulation model generated in step S28 (S30). Information processor 22 can calculate, for example, power consumption (power consumption amount) when the existing equipment (ventilation equipment, air conditioning equipment, lighting equipment, and the like) in indoor space 70 is operated under the various types of conditions acquired in step S27 so as to bring the current environment closer to a predetermined environment (target). In step S30, the power consumption (power consumption amount) of each individual equipment may be calculated, or the total power consumption (total power consumption amount) of all equipment may be calculated.

Next, information processor 22 displays the results of the executed simulations on display 24 (S31). Information processor 22 displays, on display 24, a display screen including for example, an image (a heat map image or the like) showing the three dimensional distribution of the environmental parameter, numerical values such as power consumption amount, and the like.

With the display screen as described above, environment estimation system 10 can present the environment and the power consumption (or in other words, the current environment and the current power consumption) before installation of new equipment (before renovation) to the manager or the like of the building (indoor space 70). The simulation results do not necessarily need to be presented on display 24 of information terminal 20. The simulation results may be presented by using, for example, paper on which the simulation results are printed by the salesperson of the manufacturer of the new equipment. In the case where the simulation results are provided as an electric file through a tablet terminal or the like, the salesperson can present the simulation results to the manager or the like via the tablet terminal.

The simulation data such as the BIM data, the calculation condition, the solar radiation condition, the outside air condition, the specification information, the simulation model, and the simulation results are stored in storage 23 of information terminal 20, but may be stored in a storage (not shown) included in information processing server 50. By doing so, an enormous quantity of data can be efficiently managed. Also, some or all of the processing operations shown in FIG. 4 may be executed by information processing server 50 instead of information terminal 20 (information processor 22).

### Operation Example 2: Operation for Simulating Environment After Installation of New Equipment

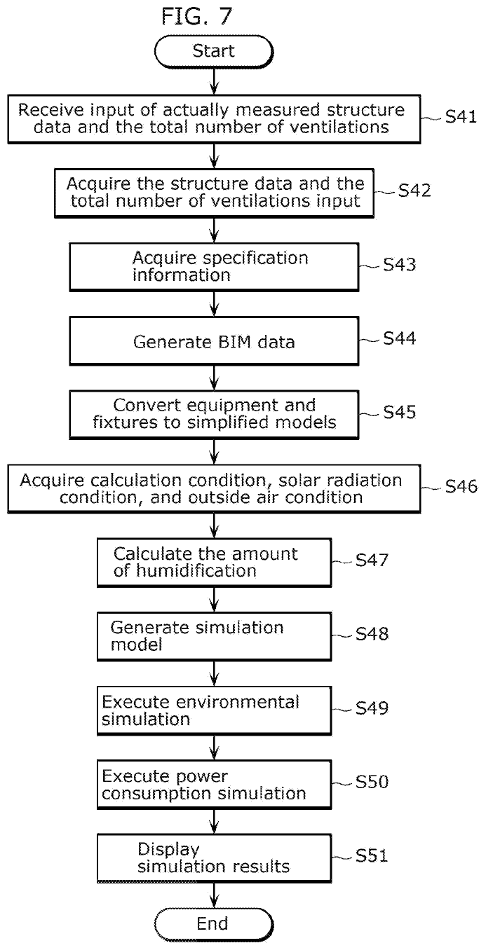

Next, a simulation operation (operation example 2) for simulating the environment of indoor space 70 in which it is assumed that new equipment has been installed will be described. FIG. 7 is a flowchart of operation example 2 performed by environment estimation system 10. In the following, the operation example 2 will be described by taking an example in which a total heat exchanger (a heat exchange ventilation system) is installed as new equipment.

First, input receiver 21 of information terminal 20 receives, from an operator who performs simulation work, an input of structure data actually measured in step S13 shown in FIG. 3 and an input of a desired number of ventilations after installation of the total heat exchanger (S41). The structure data includes size information indicating the size (volume) of indoor space 70 and arrangement information indicating the arrangement of existing equipment and existing fixture that are installed in indoor space 70. The desired number of ventilations is input based on the request of the manager or the like of the building. However, the total number of ventilations currently set (the total number of ventilations calculated in step S23) may be input. In the case where a normal number of ventilations is input by default, the operation of inputting the total number of ventilations may be omitted. Information processor 22 acquires the structure data and the total number of ventilations that were input in step S41 (S42). It can be said that the processing performed in step S42 includes processing of acquiring first information indicating the desired number of ventilations after installation of new equipment.

Next, information processor 22 acquires, from specification information management server 30, the specifications of existing equipment and existing fixtures specified by the arrangement information acquired in step S42 and specification information of the newly installed total heat exchanger (S43). The processing performed in step S43 is the same as that performed in step S24, except that the specification information of the newly installed total heat exchanger is acquired.

Next, information processor 22 generates BIM data of the building that defines indoor space 70, based on the size information and the arrangement information acquired in step S42 and the specification information acquired in step S43 (S44). The processing performed in step S44 is the same as that performed in step S25, except that data regarding the newly installed total heat exchanger is included in the BIM data.

Also, information processor 22 converts each of the equipment and the fixtures and the newly installed total heat exchanger in the generated BIM data to a simplified model by using a predetermined algorithm (S45). The processing performed in step S45 is the same as that performed in step S26, except that the newly installed total heat exchanger is converted to a simplified model.

Next, information processor 22 acquires a calculation condition, a solar radiation condition, and an outside air condition (S46). The processing performed in step S46 is the same as that performed in step S27.

Next, information processor 22 calculates the amount of humidification by the newly installed total heat exchanger on indoor space 70 based on the size information and the total number of ventilations acquired in step S42, the specification information of the newly installed total heat exchanger acquired in step S43, and the outside air condition acquired in step S46 (S47). In the case where, for example, the outside air condition indicates an ambient temperature of 15° C. and a humidity of 40%, and an ambient temperature of 20° C. and a humidity of 50% are set as a predetermined environment (target), information processor 22 calculates the amount of humidification required for the newly installed total heat exchanger to perform on indoor space 70 in order to implement the predetermined environment. The processing performed in step S47 includes processing of acquiring second information directly indicating the calculated amount of humidification.

Next, information processor 22 generates a simulation model of the environment of indoor space 70 based on the BIM data generated in steps S44 and S45, the calculation condition, the solar radiation condition, and the outside air condition acquired in step S46, and the amount of humidification calculated in step S47 (S48).

Also, information processor 22 executes an environmental simulation in indoor space 70 by using the simulation model generated in step S48 (S49). Information processor 22 can calculate, for example, a three dimensional distribution of an environmental parameter in indoor space 70 when the existing equipment (ventilation equipment, air conditioning equipment, lighting equipment, and the like) and the newly installed total heat exchanger in indoor space 70 are operated under the various types of conditions acquired in step S46 so as to bring the current environment closer to a predetermined environment (target).

Also, information processor 22 executes a power consumption simulation of the existing equipment installed in indoor space 70 and the newly installed total heat exchanger by using the simulation model generated in step S48 (S50). Information processor 22 can calculate, for example, power consumption (power consumption amount) when the existing equipment (ventilation equipment, air conditioning equipment, lighting equipment, and the like) and the newly installed total heat exchanger in indoor space 70 are operated under the various types of conditions acquired in step S46 so as to bring the current environment closer to a predetermined environment (target). In step S50, the power consumption (power consumption amount) of each individual equipment may be calculated, or the total power consumption (total power consumption amount) of all equipment may be calculated.

Next, information processor 22 displays the results of the executed simulations on display 24 (S51). Information processor 22 displays, on display 24, a display screen including for example, an image (a heat map image or the like) showing the three dimensional distribution of the environmental parameter, numerical values such as power consumption amount, and the like.

With the display screen as described above, environment estimation system 10 can present the environment and the power consumption after installation of new equipment (after renovation) to the manager or the like of the building (indoor space 70). The simulation results do not necessarily need to be presented on display 24 of information terminal 20. The simulation results may be presented by using, for example, paper on which the simulation results are printed by the salesperson of the manufacturer of the new equipment. In the case where the simulation results are provided as an electric file through a tablet terminal or the like, the salesperson can present the simulation results to the manager or the like via the tablet terminal. If it can be clearly shown that, by installing new equipment, the environment of indoor space 70 can be improved, it is possible to prompt the manager or the like of the building (indoor space 70) to determine installation of the new equipment.

The simulation data such as the BIM data, the calculation condition, the solar radiation condition, the outside air condition, the specification information, the simulation model, and the simulation results are stored in storage 23 of information terminal 20 but may be stored in a storage (not shown) included in information processing server 50. By doing so, an enormous quantity of data can be efficiently managed. Also, some or all of the processing operations shown in FIG. 7 may be executed by information processing server 50 instead of information terminal 20 (information processor 22).

Also, in operation example 2, an example was described in which a total heat exchanger is installed as new equipment. However, operation example 2 can also be applied to an environmental simulation when another equipment that has the function of humidifying indoor space 70 is installed.

### Variation

In the embodiment given above, the environmental simulation of the current environment of indoor space 70 and the environmental simulation of the environment of indoor space 70 after installation of new equipment are described using different flowcharts. However, the environmental simulation of the current environment of indoor space 70 and the environmental simulation of the environment of indoor space 70 after installation of new equipment may be performed in a single flow.

Also, when displaying simulation results, the simulation results of the current environment and the simulation results of the environment after installation of new equipment may be displayed together on a single screen. By doing so, it is possible to obtain the effect that the manager or the like can easily understand changes in the environment before and after installation of new equipment.

Also, in operation examples 1 and 2 of the embodiment, both of first information regarding the total number of ventilations for indoor space 70 and second information regarding the amount of humidification for indoor space 70 are acquired. However, it is sufficient that at least one of the first information or the second information is acquired. For example, in operation example 1, the environmental simulation in the indoor space may be performed by acquiring only either one of the first information or the second information. Also, in operation example 2, by calculating the amount of humidification by using a pre-set number of ventilations, the processing of acquiring the total number of ventilations can be omitted.

### Advantageous Effects, etc.

As described above, an environment estimation method executed by a computer such as environment estimation system 10 includes: a first acquiring step of acquiring at least one of first information regarding the total number of ventilations for indoor space 70 or second information regarding the amount of humidification for indoor space 70;
a second acquiring step of acquiring size information indicating the size of indoor space 70, arrangement information indicating the arrangement of the equipment and the fixtures in indoor space 70, and specification information of the equipment and the fixtures;
a first generating step of generating BIM data of a building that defines indoor space 70, based on the size information acquired, the arrangement information acquired, and the specification information acquired; a third acquiring step of acquiring a calculation condition that includes a mesh size set for the BIM data, a solar radiation condition, and an outside air condition; a second generating step of generating a simulation model of the environment of indoor space 70 based on the at least one of the first information or the second information acquired, the generated BIM data, the acquired calculation condition, the acquired solar radiation condition, and the acquired outside air condition; and an executing step of executing an environmental simulation in indoor space 70 by using the generated simulation model.

With the environment estimation method described above, the simulation model is generated by using at least one of the first information or the second information, and it is therefore possible to simulate the environment of indoor space 70 by taking into consideration the influence of ventilation.

Also, in operation example 1, in the first acquiring step, first information and second information are acquired. The first information is determined based on actual measurement data and indicates the total number of ventilations for indoor space 70. The second information is determined based on actual measurement data and indicates the amount of humidification for indoor space 70 performed by using air flowing into indoor space 70. In the second generating step, a simulation model is generated based on the acquired first information, the acquired second information, the generated BIM data, the acquired calculation condition, the acquired solar radiation condition, and the acquired outside air condition.

With the environment estimation method described above, it is possible to simulate the environment of indoor space 70 by taking into consideration the influence of the total number of ventilations and the amount of humidification.

Also, in operation example 2, in the first acquiring step, second information is acquired. The second information indicates the amount of humidification for indoor space 70 by the new equipment installed in indoor space 70. In the second generating step, a simulation model is generated based on the acquired second information, the generated BIM data, the acquired calculation condition, the acquired solar radiation condition, and the acquired outside air condition.

With the environment estimation method described above, it is possible to simulate the environment of indoor space 70 by taking into consideration the influence of installation of new equipment on changes in the amount of humidification.

Also, in operation example 2, the environment estimation method further includes a calculating step of calculating the amount of humidification for indoor space 70 by the newly installed equipment based on the acquired outside air condition, the specification information of the newly installed equipment, and the acquired size information. In the first acquiring step, second information that indicates the calculated amount of humidification is acquired.

With the environment estimation method described above, it is possible to simulate the environment of indoor space 70 by taking into consideration the influence of installation of new equipment on changes in the amount of humidification.

Also, in operation example 2, in the first acquiring step, first information is further acquired, the first information indicating the desired number of ventilations after installation of newly installed equipment. In the calculating step, the amount of humidification for indoor space 70 by the newly installed equipment is calculated based on the acquired outside air condition, the specification information of the newly install equipment, the acquired size information, and the acquired first information.

With the environment estimation method described above, it is possible to simulate the environment of indoor space 70 by taking into consideration the influence of installation of new equipment on changes in the amount of humidification.

Also, for example, the environment estimation method further includes a converting step of converting each of the equipment and the fixtures in the generated BIM data into a simplified model. In the second generating step, a simulation model is generated based on the at least one of the first information or the second information acquired, BIM data including the simplified model, the acquired calculation condition, the acquired solar radiation condition, and the acquired outside air condition.

With the simplified model as described above, the total number of meshes used in a simulation model is reduced, and thus the calculation time required for simulation can be shortened.

Also, for example, the simplified model is obtained by converting the actual shape of each of the equipment and the fixtures specified by the acquired specification information to a shape without a curved surface.

With the simplified model that has a shape without a curved surface, the total number of meshes of the simulation model is reduced, and it is therefore possible to shorten the calculation time required for simulation.

Also, for example, a minimum dimension of the simplified model is set to at least the smallest mesh size among mesh sizes that can be selected in the environment estimation method.

With this configuration, a mesh can be easily applied to the simplified model.

Also, for example, in the third acquiring step, the floor space of indoor space 70 is calculated based on the generated BIM data, and a mesh size that corresponds to the calculated floor space is acquired.

As described above, as a result of the mesh size being changed as appropriate according to the floor space, the calculation time required for simulation can be shortened.

Also, for example, the environment estimation method further includes a display step of displaying a result of the executed simulation.

With the environment estimation method as described above, the result of the executed simulation can be visualized.

### Other Embodiments

Up to here, an embodiment of the present invention has been described. However, the present invention is not limited to the embodiment given above.

For example, in the embodiment given above, the environment estimation system is implemented by using a plurality of devices. In this case, the structural elements included in the environment estimation system described in the embodiment given above may be assigned to the plurality of device in any way. Also, the environment estimation system may be implemented as a single device. For example, the environment estimation system may be implemented as a single device that corresponds to an information terminal. Also, the environment estimation system may be implemented as a client server system in which some of the functions of the information terminal are assigned to the information processing server.

Also, in the embodiment given above, a processing operation executed by a specific processor may be executed by a different processor. Also, the order of a plurality of processing operations may be changed. The plurality of processing operations may be performed in parallel.

Also, in the embodiment given above, the structural elements may be implemented by executing a software program suitable for the structural elements. The structural elements may also be implemented by a program executor such as a CPU or a processor reading and executing a software program recorded in a recording medium such as a hard disk or a semiconductor memory.

Also, the structural elements may be implemented by using hardware. The structural elements may be circuits (or an integrated circuit). The circuits may constitute a single circuit as a whole, or may be separate circuits. Also, the circuits may be general-purpose circuits or dedicated circuits.

Also, generic or specific aspects of the present invention may be implemented by a system, a device, a method, an integrated circuit, a computer program, or a computer-readable recording medium such as a CD-ROM, or may be implemented by any combination of a system, a device, a method, an integrated circuit, a computer program, and a recording medium.

For example, the present invention may be implemented as the environment estimation system or the information terminal according to the embodiment given above. Also, the present invention may be implemented by an environment estimation method executed by a computer such as the environment estimation system according to the embodiment given above. The present invention may also be implemented as a program (computer program product) for causing a computer to execute the environment estimation method, or may also be implemented as a computer-readable non-transitory recording medium in which the program is recorded.

The present invention also encompasses other embodiments obtained by making various modifications that can be conceived by a person having ordinary skill in the art to the above embodiment as well as embodiments implemented by any combination of the structural elements and the functions of the above embodiment without departing from the scope of the present invention.

### REFERENCE SIGNS LIST

10 environment estimation system
20 information terminal
21 input receiver
22 information processor
23 storage
24 display
25 communicator
30 specification information management server
40 weather information management server
50 information processing server
60 wide area communication network
70 indoor space

1. An environment estimation method comprising:
acquiring at least one of first information or second information, the first information being information regarding a total number of ventilations for an indoor space, the second information being information regarding an amount of humidification for the indoor space;
acquiring size information indicating a size of the indoor space, arrangement information indicating an arrangement of equipment and fixtures in the indoor space, and specification information of the equipment and the fixtures;
generating building information modeling (BIM) data of a building that defines the indoor space, based on the size information acquired, the arrangement information acquired, and the specification information acquired;
acquiring a calculation condition that includes a mesh size set for the BIM data, a solar radiation condition, and an outside air condition;
generating a simulation model of an environment of the indoor space based on the at least one of the first information or the second information acquired, the BIM data generated, the calculation condition acquired, the solar radiation condition acquired, and the outside air condition acquired; and
executing a simulation of the environment of the indoor space by using the simulation model generated.

2. The environment estimation method according to claim 1,
wherein the acquiring of the at least one of first information or second information includes acquiring the first information and the second information,
the first information indicates the total number of ventilations for the indoor space determined based on actual measurement data,
the second information indicates the amount of humidification for the indoor space performed by using air flowing into the indoor space, determined based on actual measurement data, and
the second generating includes generating the simulation model based on the first information acquired, the second information acquired, the BIM data generated, the calculation condition acquired, the solar radiation condition acquired, and the outside air condition acquired.

3. The environment estimation method according to claim 1,
wherein the acquiring of the at least one of first information or second information includes acquiring the second information,
the second information indicates the amount of humidification performed for the indoor space by newly installed equipment that is installed in the indoor space, and
the second generating includes generating the simulation model based on the second information acquired, the BIM data generated, the calculation condition acquired, the solar radiation condition acquired, and the outside air condition acquired.

4. The environment estimation method according to claim 3, further comprising:
calculating the amount of humidification performed for the indoor space by the newly installed equipment based on the outside air condition acquired, specification information of the newly installed equipment, and the size information acquired,
wherein the acquiring of the at least one of first information or second information includes acquiring the second information that indicates the amount of humidification calculated.

5. The environment estimation method according to claim 4,
wherein the acquiring of the at least one of first information or second information includes further acquiring the first information,
the first information indicates a desired number of ventilations after installation of the newly installed equipment, and
the calculating includes calculating the amount of humidification performed for the indoor space by the newly installed equipment based on the outside air condition acquired, the specification information of the newly installed equipment, the size information acquired, and the first information acquired.

6. The environment estimation method according to claim 1, further comprising:
converting each of the equipment and the fixtures in the BIM data generated to a simplified model,
wherein the second generating includes generating the simulation model based on the at least one of the first information or the second information acquired, the BIM data including the simplified model, the calculation condition acquired, the solar radiation condition acquired, and the outside air condition acquired.

7. The environment estimation method according to claim 6,
wherein the simplified model is obtained by converting an actual shape of each of the equipment and the fixtures specified by the specification information acquired to a shape without a curved surface.

8. The environment estimation method according to claim 6,
wherein a minimum dimension of the simplified model is set to at least a smallest mesh size among mesh sizes selectable in the environment estimation method.

9. The environment estimation method according to claim 1,
wherein the acquiring of the calculation condition, the solar radiation condition, and the outside air condition includes calculating a floor space of the indoor space based on the BIM data generated, and acquiring the mesh size that corresponds to the floor space calculated.

10. The environment estimation method according to claim 1, further comprising:
displaying a result of the simulation executed.

11. A computer-readable non-transitory recording medium in which a program for causing a computer to execute the environment estimation method according to claim 1 is recorded.
